(19) United States
(12) Patent Application Publication
(10) Pub. No.: US 2024/0318039 A1
(43) Pub. Date: Sep. 26, 2024

(54) CHEMICAL MECHANICAL POLISHING SLURRY AND METHOD OF MANUFACTURING SEMICONDUCTOR DEVICE USING THE SAME

(71) Applicant: Samsung Electronics Co., Ltd., Suwon-si (KR)

(72) Inventors: Yearin BYUN, Suwon-si (KR); Inkwon KIM, Suwon-si (KR); Sanghyun PARK, Suwon-si (KR)

(73) Assignee: Samsung Electronics Co., Ltd., Suwon-si (KR)

(21) Appl. No.: 18/603,614

(22) Filed: Mar. 13, 2024

(30) Foreign Application Priority Data
Mar. 24, 2023 (KR) 10-2023-0039222
Apr. 21, 2023 (KR) 10-2023-0052824

(51) Int. Cl. C09G 1/04; H01L 21/3205; H01L 21/321

(52) U.S. Cl. CPC C09G 1/04; H01L 21/3212; H01L 21/32051

(57) ABSTRACT

Provided is a chemical mechanical polishing slurry used for chemical mechanical polishing of a metal layer. The chemical mechanical polishing slurry may include deionized water, abrasive particles, and an aqueous solution including a temperature-sensitive oxidizing agent configured to control both the static etch rate and removal rate of the metal layer in a chemical mechanical polishing process when the polishing temperature of the chemical mechanical polishing process is 10° C. to 75° C.

### CROSS-REFERENCE TO RELATED APPLICATION

This application is based on and claims priority under 35 U.S.C. § 119 to Korean Patent Application Nos. 10-2023-0039222 (filed on Mar. 24, 2023 in the Korean Intellectual Property Office) and 10-2023-0052824, (filed on Apr. 21, 2023 in the Korean Intellectual Property Office), the disclosures of which are incorporated by reference herein in their entirety.

### BACKGROUND

Inventive concepts relate to a chemical mechanical polishing slurry and/or a method of manufacturing a semiconductor device using the same, and more particularly, to a chemical mechanical polishing slurry for chemical mechanical polishing of a metal layer, and/or a method of manufacturing a semiconductor device using the same.

As the degree of integration of a semiconductor device (or an integrated circuit device) increases, a multilayer wiring structure connecting functional elements, such as transistors, capacitors, and resistors, to each other is being used. To manufacture a semiconductor device having a multi-layer wiring structure, a chemical mechanical polishing process for planarizing a metal layer may be required. A chemical mechanical polishing slurry may be used for the chemical mechanical polishing process of the metal layer.

### SUMMARY

Inventive concepts provide a chemical mechanical polishing slurry that may improve the flatness of a metal layer and/or reduce the chemical mechanical polishing time during chemical mechanical polishing of the metal layer.

Inventive concepts provide a method of manufacturing a semiconductor device including a chemical mechanical polishing operation using the chemical mechanical polishing slurry.

According to an embodiment of inventive concepts, a chemical mechanical polishing slurry may include deionized water; abrasive particles; and an aqueous solution including a temperature-sensitive oxidizing agent. The temperature-sensitive oxidizing agent may be configured to control both a static etch rate of a metal layer and a removal rate of the metal layer in a chemical mechanical polishing process when a polishing temperature of the chemical mechanical polishing process is 10° C. to 75° C.

According to an embodiment of inventive concepts, a chemical mechanical polishing slurry may include deionized water; abrasive particles; a temperature-sensitive oxidizing agent configured to control both a static etch rate and a removal rate of a tungsten layer in a chemical mechanical polishing process when a polishing temperature of the chemical mechanical polishing process is 10° C. to 75° C.; a pH adjusting agent; and an aqueous solution including a catalyst.

According to an embodiment of inventive concepts, a method of manufacturing a semiconductor device may include forming an insulating pattern on a substrate, the insulating pattern including a plurality of aperture portions spaced apart from each other in a horizontal direction on the substrate; forming a metal layer on the insulating patterns, the metal layer at least partially filling the aperture portions; and performing a chemical mechanical polishing process on the metal layer using a chemical mechanical polishing slurry on a polishing pad, the insulating pattern being an etch stop film for the performing the chemical mechanical polishing process on the metal layer. The chemical mechanical polishing process may be performed at a polishing temperature in a range of 10° C. to 75° C. The chemical mechanical polishing slurry may include deionized water, abrasive particles; and an aqueous solution. The aqueous solution may include a temperature-sensitive oxidizing agent. The temperature-sensitive oxidizing agent may be configured to control both a static etch rate of the metal layer and a removal rate of the metal layer in the chemical mechanical polishing process when the polishing temperature of the chemical mechanical polishing process is 10° C. to 75° C.

### BRIEF DESCRIPTION OF THE DRAWINGS

Embodiments will be more clearly understood from the following detailed description taken in conjunction with the accompanying drawings in which:

FIG. 1 is a schematic cross-sectional view showing an example of a chemical mechanical polishing apparatus using a chemical mechanical polishing slurry according to an embodiment of technical concepts of inventive concepts;

FIG. 2 is a schematic top view showing an example of a chemical mechanical polishing apparatus using a chemical mechanical polishing slurry according to an embodiment of technical concepts of inventive concepts;

FIGS. 3 and 4 are cross-sectional views for explaining a method of manufacturing a semiconductor device including a chemical mechanical polishing operation using a chemical mechanical polishing slurry according to an embodiment of technical ideas of inventive concepts;

FIGS. 5 and 6 are diagrams illustrating a change in polishing temperature over time in a chemical mechanical polishing operation according to an embodiment of technical ideas of inventive concepts;

FIG. 7 is a diagram showing the static etch rate of a metal layer according to a polishing temperature when using a chemical mechanical polishing slurry according to an embodiment of technical ideas of inventive concepts;

FIG. 8 is a diagram showing the static etch rate of a metal layer according to polishing temperature when a chemical mechanical polishing slurry of a comparative example for comparison with FIG. 7 is used;

FIG. 9 is a diagram showing the removal rate of a metal layer according to polishing temperature when using a chemical mechanical polishing slurry according to an embodiment of technical concepts of inventive concepts and a chemical mechanical polishing slurry of a comparative example;

FIG. 10 is a diagram illustrating the recess depth of a metal pattern according to polishing temperature when using a chemical mechanical polishing slurry according to an embodiment of technical ideas of inventive concepts; and

FIG. 11 is a diagram illustrating the recess depth of a metal pattern according to polishing temperature when a chemical mechanical polishing slurry of a comparative example for comparison with FIG. 10 is used.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

In the present specification, the singular form of a constituent element may include a plurality of the constituent elements unless the context clearly indicates otherwise. In the present specification, drawings may be exaggerated to more clearly describe inventive concepts.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Embodiments of inventive concepts relate to a chemical mechanical polishing slurry configured to reduce, and capable of reducing, polishing time while improving the flatness of a metal layer, for example, a tungsten layer during chemical mechanical polishing. In some embodiments, the chemical mechanical polishing slurry may be made of deionized water, abrasive particles, and an aqueous solution including a temperature-sensitive oxidizing agent configured to control, and capable of controlling, both the static etch rate and removal rate of the metal layer when the chemical mechanical polishing temperature is about 10° C. to about 75° C.

In some embodiments, the chemical mechanical polishing slurry may include deionized water, abrasive particles, and an aqueous solution including a temperature-sensitive oxidizing agent configured to control and capable of controlling both the static etch rate and removal rate of the metal layer when the polishing temperature of chemical mechanical polishing is about 60° C. to about 75° C.

In some embodiments, the abrasive particles may include any one of silica, alumina, ceria, titania, zirconia, magnesia, germania, and mangania, or a combination thereof. The concentration of the abrasive particles may be about 1 wt % to about 10 wt % in an aqueous solution. In some embodiments, the abrasive particles may be silica, and the concentration of the silica may be about 1% wt % to about 10 wt % in the aqueous solution.

In some embodiments, the temperature-sensitive oxidizing agent (or thermo-responsive Oxidant) may include any one of Sodium Persulfate, Sodium Percarbonate, Sodium Perborate, Sodium Perborate Monohydrate, and Sodium Perborate Tetrahydrate.

In some embodiments, the temperature-sensitive oxidizing agent is Sodium Persulfate, and the concentration of the sodium persulfate may be about 0.5 wt % to about 5.0 wt % in the aqueous solution.

In some embodiments, the aqueous solution constituting the chemical mechanical polishing slurry may further include a pH adjusting agent. In some embodiments, the pH adjusting agent may include any one of potassium hydroxide (KOH), ammonium hydroxide (NH₄OH), tetra methyl amine (TMA), tetra methyl ammonium hydroxide (TMAH) and tetra ethyl amine (TEA). In some embodiments, the pH of the aqueous solution may be about 1 to about 8. In some embodiments, the pH of the aqueous solution may be about 1 to about 3.

In some embodiments, the aqueous solution constituting the chemical mechanical polishing slurry may further include a catalyst. The catalyst may include any one of ferric nitrate, potassium ferricyanide, iron chloride, iron sulfate, iron fluoride, iron bromide, copper chloride, copper fluoride, and copper bromide.

In some embodiments, the catalyst is ferric nitrate, and the concentration of the ferric nitrate may be about 1 wt % to about 2 wt % in the aqueous solution.

Hereinafter, an example of a chemical mechanical polishing apparatus using the chemical mechanical polishing slurry according to an embodiment of inventive concepts is described.

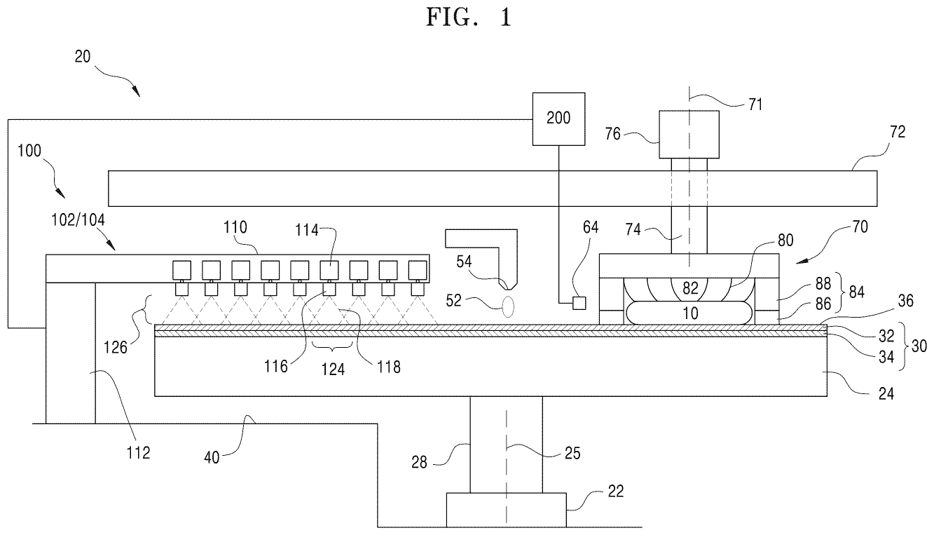

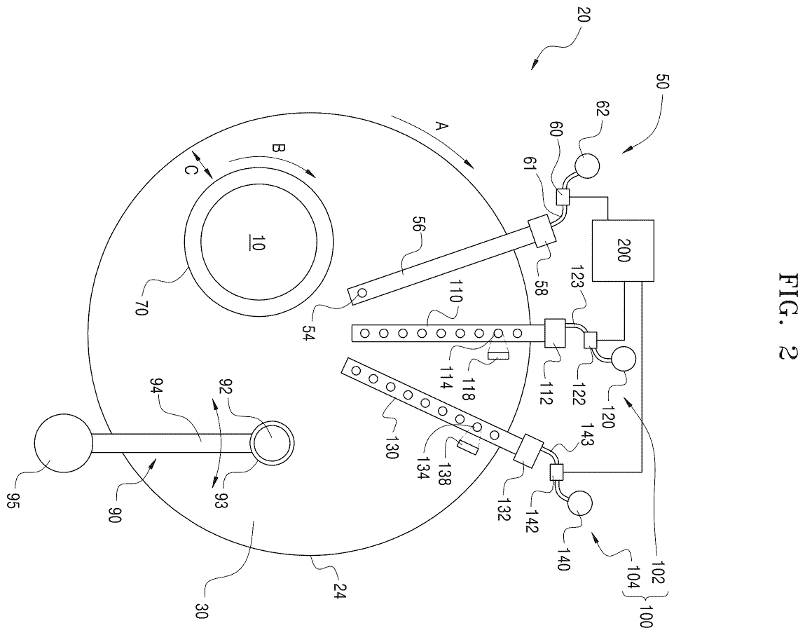

FIG. 1 is a schematic cross-sectional view showing an example of a chemical mechanical polishing apparatus using a chemical mechanical polishing slurry according to an embodiment of technical ideas of inventive concepts, and FIG. 2 is a schematic top view showing an example of a chemical mechanical polishing apparatus using a chemical mechanical polishing slurry according to an embodiment of technical concepts of inventive concepts.

Specifically, the chemical mechanical polishing apparatus 20 may include a rotatable disk-shaped platen 24 (hereinafter, referred to as platen) on which a polishing pad 30 is positioned. The chemical mechanical polishing apparatus 20 may also be referred to as a polishing station. The platen 24 may rotate about a central axis 25. The platen 24 may rotate around a central axis 25 as indicated by the arrow A in FIG. 2. A motor 22 may rotate a drive shaft 28 to rotate the platen 24.

In some embodiments, the polishing pad 30 may be a dual polishing pad including a lower polishing pad 34 and an upper polishing pad 32. The upper polishing pad 32 may be made of a softer material than the lower polishing pad 34. The chemical mechanical polishing apparatus 20 may include a polishing liquid supply system 50 for supplying the chemical mechanical polishing slurry 52 (or polishing liquid) onto the polishing pad 30 through a port 54.

The polishing liquid supply system 50 may include an arm 56 supported by a base 58 to extend over the platen 24. The port 54 may be disposed at the end of the arm 56. The port 54 may be connected to a storage or tank for storing a polishing liquid supply 62, for example, the chemical mechanical polishing slurry 52 through a control valve 60 and a pipe 61.

A carrier head 70 may operate while supporting the substrate 10 in contact with the polishing pad 30. As described below, the substrate 10 may be a substrate structure having a metal layer formed thereon. The carrier head 70 may be referred to as a polishing head. The carrier head 70 may be coupled to a support structure 72. The carrier head 70 is connected to the rotary motor 76 by the drive shaft 74 so that the carrier head 70 may rotate around the shaft 71.

The carrier head 70 may include a flexible membrane 80 having a substrate mounting surface for contacting the backside (or rear side) of the substrate 10, and a pressurization chamber 82 for applying pressure to the substrate 10. The carrier head 70 may include a retaining ring 84 for supporting (holding) the substrate 10. The retaining ring 84 may include a lower retaining ring 86 and an upper retaining ring 88.

During the operation of the chemical mechanical polishing apparatus 20, the platen 24 is rotated about the central axis 25, and the carrier head 70 may be rotated about the central shaft 71 as shown by the arrow B in FIG. 2 and may be moved laterally across the top surface of the polishing pad 30 as shown by the arrow C in FIG. 2.

The chemical mechanical polishing apparatus 20 may include a pad conditioner 90 having a conditioner disk 92 held by a conditioner head 93 at the end of a conditioner arm 94. The conditioner disk 92 may be used to maintain the surface roughness of the polishing pad 30. The conditioner arm 94 may be supported by the conditioner base 95.

The chemical mechanical polishing apparatus 20 may include a temperature sensor 64 for monitoring the temperature of the chemical mechanical polishing slurry 52 on the polishing pad 30 and/or the polishing pad 30. For example, the temperature sensor 64 is located on the polishing pad 30, and an infrared (IR) sensor configured to measure the temperature of the chemical mechanical polishing slurry 52 on the polishing pad 30 and/or the polishing pad 30 may be, for example, an IR camera.

The temperature sensor 64 may be configured to measure temperature at multiple points along the radius of polishing pad 30 to create a radial temperature profile. For example, an IR camera constituting the temperature sensor 64 may have a field of view extending over the radius of the polishing pad 30.

In some embodiments, the temperature sensor 64 may be a contact sensor rather than a non-contact sensor as in FIG. 1. For example, the temperature sensor 64 may be a thermocouple or IR thermometer located on or in the platen 24. The temperature sensor 64 may directly contact the polishing pad 30. In some embodiments, a plurality of temperature sensors 64 may be spaced apart from each other at radial positions of the polishing pad 30 to provide temperatures at multiple points along the radius of the polishing pad 30.

The temperature sensor 64 is illustrated in FIG. 1 as being positioned to monitor the temperature of the polishing pad 30 and/or the chemical mechanical polishing slurry 52 on the polishing pad 30 but the temperature sensor 64 may be located inside the carrier head 70 to measure the temperature of the substrate 10. The temperature sensor 64 may be a contact sensor that directly contacts the substrate 10, that is, a semiconductor wafer.

The chemical mechanical polishing apparatus 20 may include a temperature control system 100 for controlling the temperature of the chemical mechanical polishing slurry 52 on the polishing pad 30 and/or the polishing pad 30. The temperature control system 100 may deliver a temperature controlled fluid onto the polishing surface 36 of the polishing pad 30. The temperature control system 100 may transfer temperature controlled fluids 118 and 138 onto the chemical mechanical polishing slurry 52 already present on the polishing pad 30. The temperature control system 100 may include a heating system 102 and a cooling system 104.

The heating system 102 may deliver the heating fluid 118, for example hot water or steam. The cooling system 104 may deliver the cooling fluid 138, for example chilled water or cooling air. The heating fluid 118 and the cooling fluid 138 may be delivered through nozzles 116 and apertures 114 and 134 provided by arms 110 and 130.

In some embodiments, the heating system 102 may include an arm 110 extending from the edge of the polishing pad 30 to or at least near the center of the polishing pad 30 at the top of the platen 24 and the polishing pad 30. The arm 110 may be supported by the base 112. The base 112 may be supported on the same frame 40 as the platen 24.

The base 112 may include one or more actuators, such as linear actuators for raising or lowering the arm 110 and/or a rotary actuator for swinging the arm 110 laterally over the platen 24. The arm 110 may be positioned to avoid collision with other hardware components, such as the carrier head 70, the pad conditioning disk 92, a chemical mechanical polishing slurry supply arm 56, and the cooling fluid supply arm 130.

A plurality of apertures 114 are formed in the lowermost surface of the arm 110. The aperture 114 may be configured to direct the heating fluid 118, for example, gas or vapor (or steam) onto the polishing pad 30. In some embodiments, the aperture 114 may be connected with a nozzle 116 that directs the ejected heating fluid 118 in the form of a spray onto the polishing pad 30. Although the aperture 114 and the nozzle 116 are shown separately in FIG. 1, the aperture 114 and the nozzle 116 may be one body, or the nozzle 116 may not be connected and the heating fluid 118 may be discharged directly through the aperture 114 in the form of a spray.

The aperture 114 may direct the heating fluid 118 in a radial pattern 124 on the polishing pad 30. In FIG. 2, although the apertures 114 are shown as being equally spaced, this is not required. The apertures 114 may be more densely clustered toward the center of the polishing pad 30. FIG. 2 illustrates nine apertures 114, but more or fewer apertures 114 may be present.

The arm 110 may be supported by the base 112 to be spaced apart from the polishing pad 30. A separation distance 126 between the aperture 114 (and/or the nozzle 116) and the polishing pad 30 may be about 0.5 to about 5 mm. In particular, the separation distance 126 may be selected such that the heat of the heating fluid 118 does not significantly dissipate before the heating fluid 118 reaches the polishing pad 30. For example, the separation distance 126 may be selected such that the heating fluid 118 emitted from the aperture 114 does not condense before reaching the polishing pad 30.

The heating system 102 may include a supply source 120 of the heating fluid 118, and the supply source 120 may be connected to the arm 110 through a control valve 122 and a fluid pipe 123. In some embodiments, the supply source 120 may be a steam generator, for example, a vessel in which water is boiled to produce steam gas.

The heating fluid 118 may be mixed with other gases (e.g., air) and/or liquids (e.g., heated water), or the heating fluid 118 may be substantially pure steam. When steam is used as the heating fluid 118, wherein the steam is generated in the fluid supply source 120, the temperature of the steam may be about 90° C. to about 200° C. The temperature of the steam may be, for example, about 90° C. to about 150° C. due to heat loss during transport as the steam is dispensed through the aperture 114. In some embodiments, steam may be delivered by the aperture 114 at a temperature between about 60° C. and about 100° C., such as between about 60° C. and about 75° C.

The chemical mechanical polishing apparatus 20 may include a cooling system 104. The cooling system 104 may be configured similarly to the heating system 102 as described above. The arm 130 may be supported by the base 132. The arm 130 may be connected to the supply source 140 through the control valve 142 and the pipe 143. However, the supply source 140 is a supply source of the cooling fluid 138, and the cooling system 104 may supply the cooling fluid 138 onto the polishing pad 30 in a spray form.

The cooling fluid 138 may be a liquid, for example, water below 20° C., gas below 20° C., or a mixture of liquid and gas. The cooling fluid 138 may be air with aerosolized water droplets. The aperture 134 may have the same configuration as the aforementioned aperture 114 supplying the heating fluid 118. The aperture 134 may have the same connection configuration as the nozzle 116 described above.

The chemical mechanical polishing apparatus 20 includes various components, for example, a controller 200 for controlling the operation of the polishing liquid supply system 50 and the temperature control system 100. The controller 200 may be configured to receive a temperature measurement value from the temperature sensor 64. The controller 200 may control the control valves 122 and/or 142 to control the flow rate of heating fluid and/or cooling fluid onto the polishing pad 30 to compare the measured temperature with the target temperature, and to achieve the target temperature.

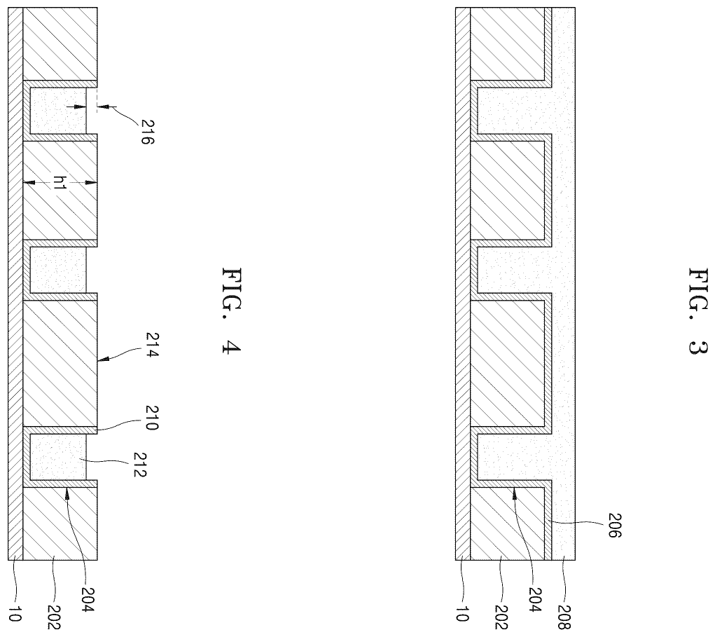

FIGS. 3 and 4 are cross-sectional views for explaining a method of manufacturing a semiconductor device including a chemical mechanical polishing operation using a chemical mechanical polishing slurry according to an embodiment of technical ideas of inventive concepts.

Specifically, the method of manufacturing the semiconductor device of FIGS. 3 and 4 may include a chemical mechanical polishing operation (process). The chemical mechanical polishing operation may be performed using the chemical mechanical polishing apparatus 20 of FIGS. 1 and 2.

Referring to FIG. 3, an insulating pattern 202 having a plurality of aperture portions 204 spaced apart from each other in the horizontal direction is formed on a substrate 10. After forming an insulating film on the substrate 10, the insulating film is selectively etched using a photolithography process to form aperture portions 204 exposing desired and/or alternatively preset areas of the substrate 10, so that an insulating pattern 202 may be obtained.

The substrate 10 may use various substrates used in manufacturing semiconductor devices. In some embodiments, the substrate 10 may use a silicon substrate. The insulating pattern 202 may include an oxide film-based material and/or a nitride film-based material. For example, the insulating pattern 202 may be formed using any one of Boron PhosphoSilicate Glass (BPSG), PhosphoSilicate Glass (PSG), High Density Plasma (HDP), Tetra Ethyl Ortho Silicate (TEOS), and Undoped Silica Glass (USG).

The insulating pattern 202 may be formed using a physical vapor deposition (PVD) method, a chemical vapor deposition (CVD) method, a metal organic CVD (MOCVD) method, or an atomic layer deposition (ALD) method. The insulating pattern 202 may include aperture portions 204 exposing preset regions of the substrate 10 to form wires and/or plugs. The aperture portions 204 may be line-shaped trenches.

A barrier layer 206 is formed on the insulating pattern 202 and the substrate 10. The barrier layer 206 may be formed of titanium nitride or the like. The barrier layer 206 may not be formed if necessary. Subsequently, a metal layer 208 is formed on the barrier layer 206 to sufficiently bury the aperture portions 204. In some embodiments, the metal layer 208 may be a tungsten film.

Referring to FIG. 4, as described above, on the polishing pad 30 (see FIGS. 1 and 2) of the chemical mechanical polishing apparatus 20 (see FIGS. 1 and 2), the metal layer 208 is chemically mechanically polished using a chemical mechanical polishing slurry 52 (see FIG. 1) as an etch stop film on a surface 214 of the insulating pattern 202. The insulating pattern 202 may be used as an etch stop film for polishing the metal layer 208 and the barrier layer 206.

A barrier pattern 210 and a metal pattern 212 may be formed in the aperture portions 204 by chemical mechanical polishing of the metal layer 208. The metal pattern 212 may be recessed from the surface 214 of the insulating pattern 202 by chemical mechanical polishing. When a recess depth 216 of the metal pattern 212 is low, planarity of the metal pattern 212 may be improved. In some embodiments, the recess depth 216 may be 5% or less (and/or 1% to 5%) of the height h1 of the insulating pattern 202.

A chemical mechanical polishing operation (process) may be performed by a combination of mechanical abrasion and chemical etching of the metal layer 208 at the interface between the metal layer 208 on the substrate 10 and the polishing pad 30 using a chemical mechanical polishing slurry 52 (see FIG. 1).

As previously explained, a polishing temperature, for example, the temperature of the chemical mechanical polishing slurry 52 (see FIG. 1) or heating fluid or cooling fluid is supplied to the chemical mechanical polishing slurry 52 (see FIG. 1) supplied on the polishing pad 30 (see FIGS. 1 and 2) so that the chemical mechanical polishing operation (process) may control the polishing temperature.

Accordingly, embodiments of inventive concepts relate to a chemical mechanical polishing slurry configured to adjust and capable of adjusting the static etch rate and removal rate (or removal rate) of the metal layer 208 by controlling the polishing temperature in the chemical mechanical polishing operation (process).

When using the chemical mechanical polishing slurry according to an embodiment of inventive concepts, the chemical mechanical polishing operation may shorten the polishing time and improve the planarity of the metal pattern 212. This will be explained in more detail below. The change of the polishing temperature with time in the chemical mechanical polishing operation (process) is first described.

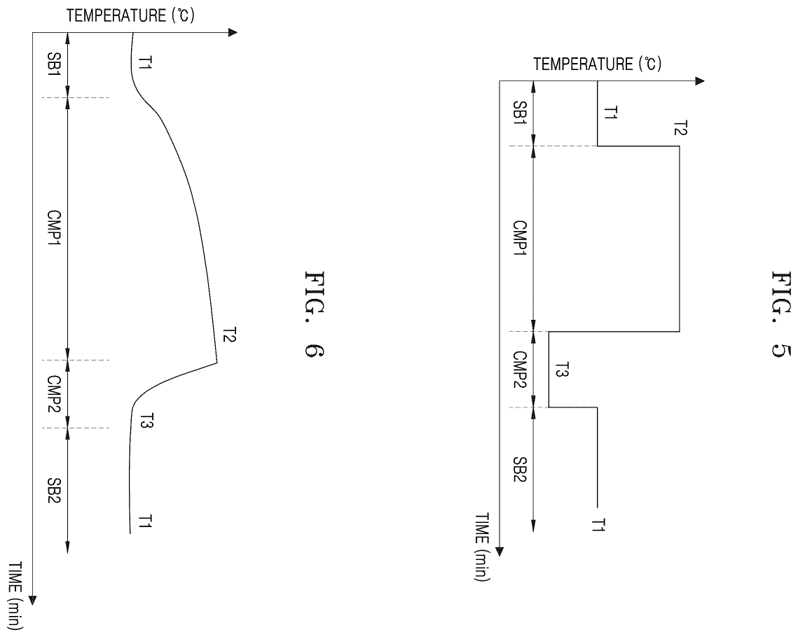

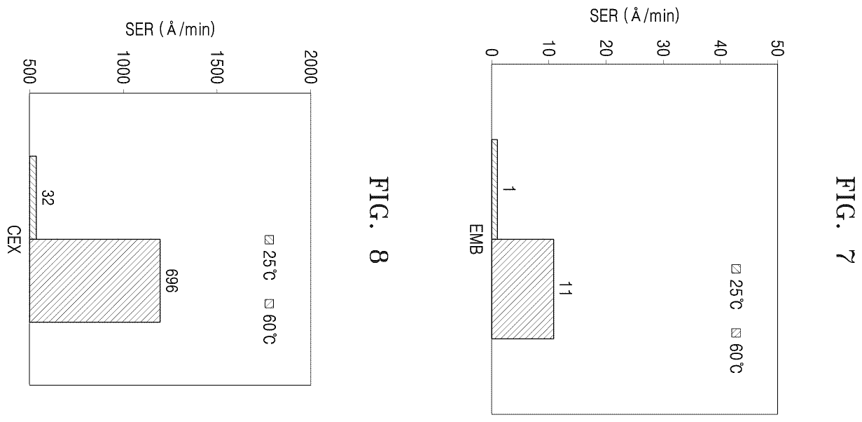

FIGS. 5 and 6 are diagrams illustrating a change in polishing temperature over time in a chemical mechanical polishing operation according to an embodiment of technical ideas of inventive concepts.

In detail, the chemical mechanical polishing operation may be performed using the chemical mechanical polishing apparatus 20 of FIGS. 1 and 2. The chemical mechanical polishing operation may be chemical mechanical polishing of the metal layer 208 of FIGS. 3 and 4. The chemical mechanical polishing operation may include a first standby operation SB1, a first chemical mechanical polishing operation CMP1, a second chemical mechanical polishing operation CMP2, and a second standby operation SB2.

In the first standby operation SB1 and the second standby operation SB2, the polishing temperature, that is, the temperature of the chemical mechanical polishing slurry 52 (see FIGS. 1 and 2), may be T1. In some embodiments, T1 may be 20° C.

In some embodiments, the first chemical mechanical polishing operation CMP1 may be chemical mechanical polishing of the metal layer 208 first by raising the temperature of the chemical mechanical polishing slurry to T2, for example, about 25° C. to about 75° C. In some embodiments, the first chemical mechanical polishing operation CMP1 may be chemical mechanical polishing of the metal layer 208 first by raising the temperature of the chemical mechanical polishing slurry to T2, for example, about 60° C. to about 75° C.

In FIG. 5, the polishing temperature may be rapidly increased from the first standby operation SB1 to the first chemical mechanical polishing operation CMP1. In FIG. 6, the polishing temperature may be gradually increased from the first standby operation SB1 to the first chemical mechanical polishing operation CMP1.

The second chemical mechanical polishing operation CMP2 may be chemical mechanical polishing of the metal layer 208 secondarily by lowering the temperature of the chemical mechanical polishing slurry to the temperature T3, for example, about 10° C. to about 20° C. In FIG. 5, the polishing temperature may be rapidly decreased from the first chemical mechanical polishing operation CMP1 to the second chemical mechanical polishing operation CMP2. In FIG. 6, the polishing temperature may be gradually decreased from the first chemical mechanical polishing operation CMP1 to the second chemical mechanical polishing operation CMP2. In FIG. 6, the polishing temperature of the second chemical mechanical polishing operation CMP2 or the second standby operation SB2 may be substantially the same.

In the chemical mechanical polishing operation according to an embodiment of inventive concepts, the chemical mechanical polishing slurry 52 (see FIG. 1) may shorten the polishing time and improve the planarity of the metal pattern 212 in the range of T1 to T3, such as in the polishing temperature range of about 15° C. to about 75° C. In addition, in the chemical mechanical polishing operation according to an embodiment of inventive concepts, the chemical mechanical polishing slurry 52 (see FIG. 1) may shorten the polishing time and improve the planarity of the metal pattern 212 even in the T2 range, for example, in the polishing temperature range of about 60° C. to about 75° C.

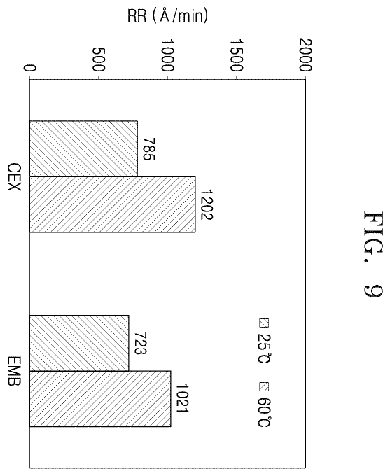

FIG. 7 is a diagram showing the static etch rate of a metal layer according to the polishing temperature when using a chemical mechanical polishing slurry according to an embodiment of technical ideas of inventive concepts, and FIG. 8 is a diagram showing the static etch rate of a metal layer according to polishing temperature when a chemical mechanical polishing slurry of a comparative example for comparison with FIG. 7 is used.

Specifically, the manufacturing process of the chemical mechanical polishing slurry EMB according to an embodiment shown in FIG. 7 is as follows. 0.1 wt % of silica as abrasive particles and ferric nitrate as a catalyst are added to deionized water. By adding sodium persulfate as a temperature-sensitive oxidizing agent to deionized water including silica and ferric nitrate, the chemical mechanical polishing slurry EMB is prepared according to an embodiment.

The manufacturing process of the chemical mechanical polishing slurry CEX according to the comparative example shown in FIG. 8 is as follows. 0.1 wt % of silica as abrasive particles and ferric nitrate as a catalyst are added to deionized water. By adding hydrogen peroxide as an oxidizing agent to deionized water containing silica and ferric nitrate, in the comparative example, chemical mechanical polishing slurry CEX is prepared.

Using the chemical mechanical polishing slurry EMB according to an embodiment and the chemical mechanical polishing slurry CEX of the comparative example, the static etch rate SER of the substrate is evaluated. After etching the metal layer by putting the substrate into the chemical mechanical polishing slurry EMB according to an embodiment and the chemical mechanical polishing slurry CEX of the comparative example, the static etch rate SER is based on the result of measuring the amount of etching reduction of the metal layer.

When using the chemical mechanical polishing slurry EMB according to an embodiment, at a polishing temperature of 25° C., the static etch rate SER of a metal layer, for example, a tungsten layer, is 1 Å/min and the static etch rate SER of the metal layer at a polishing temperature of 60° C. is 11 Å/min. When using the chemical mechanical polishing slurry EMB according to an embodiment, even when the polishing temperature increases from 25° C. to 60° C., the static etch rate SER of the metal layer does not increase significantly and remains low.

When using the chemical mechanical polishing slurry CEX of the comparative example, at a polishing temperature of 25° C., the static etch rate SER of the metal layer is 32 Å/min, and at a polishing temperature of 60° C., the static etch rate SER of the metal layer is 696 Å/min. When using the chemical mechanical polishing slurry CEX of the comparative example, as the polishing temperature rises from 25° C. to 60° C., the static etch rate SER of the metal layer may be greatly increased.

When using the chemical mechanical polishing slurry CEX of the comparative example, as the polishing temperature rises, since the static etch rate of the metal layer increases significantly, as the polishing temperature rises, the previously described recess depth of the metal pattern may increase, and accordingly, the planarity of the metal pattern may decrease. In contrast, when using the chemical mechanical polishing slurry EMB according to an embodiment of inventive concepts, as the polishing temperature rises, since the static etch rate of the metal layer does not increase significantly, as the polishing temperature rises, the depth of the recess of the metal pattern described above decreases, and the planarity of the metal pattern may increase.

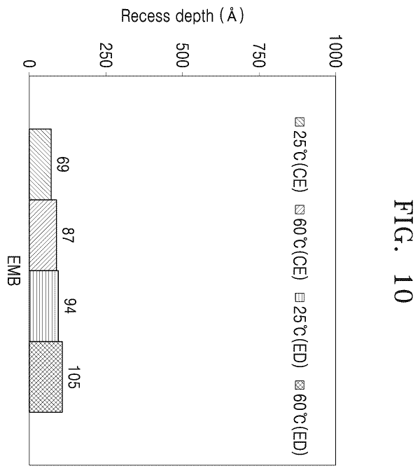

FIG. 9 is a diagram showing the removal rate of a metal layer according to polishing temperature when a chemical mechanical polishing slurry according to an embodiment of an embodiment of technical concepts of inventive concepts and a chemical mechanical polishing slurry according to the comparative example are used.

Specifically, since the manufacturing processes of the chemical mechanical polishing slurry EMB according to an embodiment and the chemical mechanical polishing slurry CEX according to the comparative example have been described with reference to FIGS. 7 and 8, the description thereof is omitted here.

Using the chemical mechanical polishing slurry EMB according to an embodiment and the chemical mechanical polishing slurry CEX of the comparative example, the removal rate RR (or polishing rate) of the metal layer at the time of chemical mechanical polishing of the metal layer (e.g., tungsten layer) is evaluated. Since chemical mechanical polishing has been previously described with reference to FIGS. 3 and 4, the description thereof is omitted here.

When using the chemical mechanical polishing slurry EMB according to an embodiment, the removal rate RR of a metal layer, such as a tungsten layer, at a polishing temperature of 25° C., is 723 Å/min, and the removal rate RR of the metal layer, at a polishing temperature of 60° C., is 1021 Å/min. If using the chemical mechanical polishing slurry EMB according to an embodiment, when the polishing temperature increases from about 25° C. to about 60° C., the removal rate RR of the metal layer may increase.

When using the chemical mechanical polishing slurry CEX of the comparative example, the removal rate RR of the metal layer at a polishing temperature of 25° C. is 785 Å/min and the removal rate RR of the metal layer at a polishing temperature of 60° C. is 1202 Å/min. When using the chemical mechanical polishing slurry CEX of the comparative example, as the polishing temperature is increased from 25° C. to 60° C., the removal rate RR of the metal layer may be increased. When using the chemical mechanical polishing slurry EMB according to an embodiment of inventive concepts, as the polishing temperature rises, the removal rate RR of the metal layer increases, thereby reducing the polishing time.

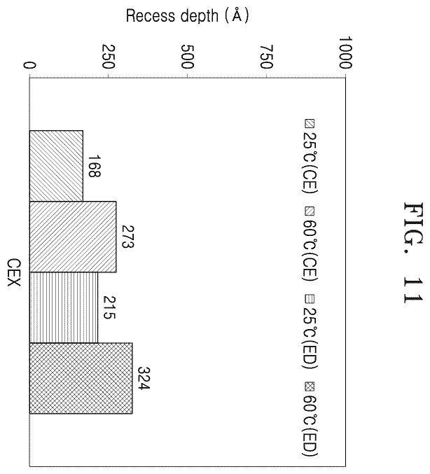

FIG. 10 is a view showing the recess depth of a metal pattern according to polishing temperature when using a chemical mechanical polishing slurry according to an embodiment of technical ideas of inventive concepts, and FIG. 11 is a diagram illustrating the recess depth of a metal pattern according to a polishing temperature when a chemical mechanical polishing slurry of a comparative example for comparison with FIG. 10 is used.

Specifically, since the manufacturing processes of the chemical mechanical polishing slurry EMB according to an embodiment and the chemical mechanical polishing slurry CEX according to the comparative example have been described with reference to FIGS. 7 and 8, the description thereof is omitted here.

Using the chemical mechanical polishing slurry EMB according to an embodiment and the chemical mechanical polishing slurry CEX of the comparative example, the recess depth of the metal pattern upon chemical mechanical polishing of the metal layer (e.g., tungsten layer) is evaluated. Since chemical mechanical polishing has been previously described with reference to FIGS. 3 and 4, the description thereof is omitted here.

When using the chemical mechanical polishing slurry EMB according to an embodiment, at a polishing temperature of 25° C., a metal pattern of the substrate edge portion CE, for example, a tungsten pattern, has a recess depth of 69 Å, and at a polishing temperature of 60° C., the recess depth of the metal pattern of the edge portion CE of the substrate is 87 Å.

In addition, when using the chemical mechanical polishing slurry EMB according to an embodiment, at a polishing temperature of 25° C., the recess depth of the metal pattern of the central portion CC of the substrate is 94 Å, and at a polishing temperature of 60° C., the recess depth of the metal pattern of the central portion CE of the substrate is 105 Å.

When using the chemical mechanical polishing slurry CEX of the comparative example, at a polishing temperature of 25° C., the recess depth of the metal pattern of the edge portion CE of the substrate is 168 Å, and at a polishing temperature of 60° C., the recess depth of the metal pattern of the edge portion CE of the substrate is 273 Å.

In addition, when using the chemical mechanical polishing slurry CEX of the comparative example, at a polishing temperature of 25° C., the recess depth of the metal pattern of the central portion CC of the substrate is 215 Å, and at a polishing temperature of 60° C., the recess depth of the metal pattern of the central portion CE of the substrate is 324 Å.

When using the chemical mechanical polishing slurry EMB according to an embodiment, compared to the case of using the chemical mechanical polishing slurry CEX of the comparative example, the recess depth of the metal pattern is low according to the polishing temperature and the recess depth of the metal pattern does not greatly increase even when the polishing temperature is increased. Accordingly, when using the chemical mechanical polishing slurry EMB according to an embodiment of technical ideas of inventive concepts, depending on the polishing temperature, the depth of the recess of the metal pattern may be made small, and accordingly, the planarity of the metal pattern may be increased.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to embodiments thereof, it will be understood that various changes in form and details may be made therein without departing from the spirit and scope of the following claims.

What is claimed is:

1. A chemical mechanical polishing slurry, the chemical mechanical polishing slurry comprising:
deionized water;
abrasive particles; and
an aqueous solution including a temperature-sensitive oxidizing agent, the temperature-sensitive oxidizing agent being configured to control both a static etch rate of a metal layer and a removal rate of the metal layer in a chemical mechanical polishing process when a polishing temperature of the chemical mechanical polishing process is 10° C. to 75° C.

2. The chemical mechanical polishing slurry of claim 1, wherein the abrasive particles comprise at least one of silica, alumina, ceria, titania, zirconia, magnesia, germania, and mangania.

3. The chemical mechanical polishing slurry of claim 1, wherein a concentration of the abrasive particles is 1 wt % to 10 wt % in the aqueous solution.

4. The chemical mechanical polishing slurry of claim 1, wherein the temperature-sensitive oxidizing agent comprises at least one of Sodium Persulfate, Sodium Percarbonate, Sodium Perborate, Sodium Perborate Monohydrate, and Sodium Perborate Tetrahydrate.

5. The chemical mechanical polishing slurry of claim 1, wherein the aqueous solution further comprises a pH adjusting agent.

6. The chemical mechanical polishing slurry of claim 5, wherein the pH adjusting agent comprises at least one of potassium hydroxide (KOH), ammonium hydroxide (NH₄OH), tetramethylamine (TMA), tetramethylammonium hydroxide (TMAH), and tetraethylamine (TEA).

7. The chemical mechanical polishing slurry of claim 5, wherein a pH of the aqueous solution is 1 to 8.

8. The chemical mechanical polishing slurry of claim 1, wherein the aqueous solution further comprises a catalyst.

9. The chemical mechanical polishing slurry of claim 8, wherein the catalyst comprises at least one of ferric nitrate, potassium ferricyanide, iron chloride, iron sulfate, iron fluoride, iron bromide, copper chloride, copper fluoride, and copper bromide.

10. A chemical mechanical polishing slurry, the chemical mechanical polishing slurry comprising:
deionized water;
abrasive particles;
a temperature-sensitive oxidizing agent configured to control both a static etch rate and a removal rate of a tungsten layer in a chemical mechanical polishing process when a polishing temperature of the chemical mechanical polishing process is 10° C. to 75° C.;
a pH adjusting agent; and
an aqueous solution including a catalyst.

11. The chemical mechanical polishing slurry of claim 10, wherein
the abrasive particles comprise silica, and
a concentration of the silica is 1 wt % to 10 wt % in the aqueous solution.

12. The chemical mechanical polishing slurry of claim 10, wherein
the temperature-sensitive oxidizing agent comprises sodium persulfate, and
a concentration of the sodium persulfate is 0.5 wt % to 5 wt % in the aqueous solution.

13. The chemical mechanical polishing slurry of claim 10, wherein
the pH adjusting agent comprises at least one of potassium hydroxide (KOH), ammonium hydroxide (NH₄OH), tetramethylamine (TMA), tetramethylammonium hydroxide (TMAH) and tetraethylamine (TEA), and
the aqueous solution has a pH of 1 to 8.

14. The chemical mechanical polishing slurry of claim 10, wherein
the catalyst comprises ferric nitrate, and
a concentration of ferric nitrate is 1 wt % to 2 wt % in the aqueous solution.

15. A method of manufacturing a semiconductor device, the method comprising:
forming an insulating pattern on a substrate, the insulating pattern including a plurality of aperture portions spaced apart from each other in a horizontal direction on the substrate;
forming a metal layer on the insulating patterns, the metal layer at least partially filling the aperture portions; and
performing a chemical mechanical polishing process on the metal layer using a chemical mechanical polishing slurry on a polishing pad, the insulating pattern being an etch stop film for the performing the chemical mechanical polishing process on the metal layer, wherein
the chemical mechanical polishing process is performed at a polishing temperature in a range of 10° C. to 75° C.,
the chemical mechanical polishing slurry comprises deionized water, abrasive particles;
and an aqueous solution,
the aqueous solution includes a temperature-sensitive oxidizing agent, and the temperature-sensitive oxidizing agent is configured to control both a static etch rate of the metal layer and a removal rate of the metal layer in the chemical mechanical polishing process when the polishing temperature of the chemical mechanical polishing process is 10° C. to 75° C.

16. The method of claim 15, wherein the chemical mechanical polishing process comprises:
performing a first chemical mechanical polishing of the metal layer when a temperature of the chemical mechanical polishing slurry is 60° C. to 75° C.; and
performing secondary chemical mechanical polishing of the metal layer when the temperature of the chemical mechanical polishing slurry is 10° C. to 20° C.

17. The method of claim 15, wherein
the chemical mechanical polishing process comprises performing chemical mechanical polishing of the metal layer to form a plurality of metal patterns buried in the aperture portions,
the plurality of metal patterns are recessed from a surface of the insulating pattern, and
the plurality of metal patterns have recess depths of 5% or less of a height of the insulating pattern.

18. The method of claim 15, wherein
the metal layer includes a tungsten layer,
the abrasive particles comprise silica, and
a silica concentration is 1 wt % to 10 wt % in the aqueous solution.

19. The method of claim 15, wherein
the temperature-sensitive oxidizing agent included in the chemical mechanical polishing slurry comprises sodium persulfate, and
a concentration of the sodium persulfate is 0.5 wt % to 5 wt % in the aqueous solution.

20. The method of claim 15, wherein
the chemical mechanical polishing slurry comprises a pH adjusting agent and a catalyst,
the pH adjusting agent is at least one of potassium hydroxide (KOH), ammonium hydroxide (NH₄OH), tetramethylamine (TMA), tetramethylammonium hydroxide (TMAH) and tetraethylamine (TEA), and
the catalyst comprises ferric nitrate.
